(19) United States
(12) Patent Application Publication
(10) Pub. No.: US 2024/0224720 A1
(43) Pub. Date: Jul. 4, 2024

(54) DISPLAY DEVICE

(71) Applicant: LG Display Co., Ltd., Seoul (KR)

(72) Inventor: JeongJae Ban, Paju-si (KR)

(73) Assignee: LG Display Co., Ltd., Seoul (KR)

(21) Appl. No.: 18/131,897

(22) Filed: Apr. 7, 2023

(30) Foreign Application Priority Data
Dec. 30, 2022 (KR) 10-2022-0190854

(51) Int. Cl. H10K 59/80; H10K 59/124

(52) U.S. Cl. CPC H10K 59/873; H10K 59/124

(57) ABSTRACT

According to an aspect of the present disclosure, a display device may include a substrate including a first non-active area in which a hole is disposed, an active area which encloses the first non-active area, and a second non-active area which encloses the active area; a first inorganic layer disposed on the substrate; a plurality of patterns and a dam disposed to enclose the hole on the first inorganic layer of the first non-active area; and a crack prevention unit which is disposed in the dam and is disposed on the substrate exposed from the first inorganic layer which is partially open.

### CROSS-REFERENCE TO RELATED APPLICATIONS

This application claims the priority of Korean Patent Application No. 10-2022-0190854 filed on Dec. 30, 2022, in the Korean Intellectual Property Office, the disclosure of which is incorporated herein by reference for all proposes.

### BACKGROUND

### Technical Field

The present disclosure relates to a display device, and more particularly, for example, without limitation, to a display device which is capable of reducing moisture permeation.

### Discussion of the Related Art

A display device may be used for various types of devices, such as TVs, monitors, tablet computers, navigations, game players, wearable device and mobile phones. As such a display device, various types of display devices, such as a liquid crystal display (LCD) device, plasma display panel (PDP) devices, field emission display (FED) devices, electroluminescence display (ELD) devices, electrophoretic display devices (FPDs) or an organic light emitting display (OLED) device, have been used.

The display device is being developed by adding a camera, a speaker, and/or a sensor. Specifically, in order to dispose a sensor, such as a camera, in the display device, a hole-in-display structure in which a hole is disposed in the display device is applied.

The description provided in the related art section should not be assumed to be prior art merely because it is mentioned in or associated with the related art section. The related art section may include information that describes one or more aspects of the subject technology.

### SUMMARY

It is newly recognized by the inventor of the present application that, when a hole is disposed to pass through the substrate and the other components on the substrate to dispose a component such as a camera or a photo sensor in an active area of the display device, a crack may be caused in the substrate and the other components on the substrate, due to the stress generated when the hole is disposed. Specifically, in the inorganic layers formed of an inorganic material which is vulnerable to the stress, a probability of cracks caused when the hole is disposed may be higher. Further, an end of the inorganic layer which is exposed to the outside by the crack may serve as a start point of the moisture permeation. Accordingly, the moisture permeation is generated from the start point of the moisture permeation to the active area, and a quality of the display device is degraded.

Thus, the inventor of present application noticed that, the longer the distance along which the crack is generated, that is, the closer the position of the moisture permeation start point to the active area, the shorter the moisture permeation path through which the moisture permeation reaches the active area. The longer the distance along which the crack is generated, the easier the moisture permeation occurs in the active area and the worse the quality of the display device.

Accordingly, embodiments of the present disclosure are directed to a display device that substantially obviate one or more of the issues due to limitations and disadvantages of the related art.

Thus, an aspect of the present disclosure is to provide a display device which is capable of reducing or minimizing propagation of cracks through an inorganic layer.

Another aspect of the present disclosure is to provide a display device which is capable of reducing or minimizing moisture permeation.

Still another aspect of the present disclosure is to improve a display quality of a display device by reducing or minimizing the recognition of a crack prevention unit in a first non-active area disposed in an active area.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises: a substrate including a first non-active area in which a hole is disposed, an active area which encloses the first non-active area, and a second non-active area which encloses the active area; a first inorganic layer disposed on the substrate; a plurality of patterns and a dam disposed to enclose the hole on the first inorganic layer of the first non-active area; and a crack prevention unit which is disposed in the dam and is disposed on the substrate exposed from the first inorganic layer which is partially open.

In another aspect, a display device comprises: a substrate including a first non-active area in which a hole is disposed, an active area which encloses the first non-active area, and a second non-active area which encloses the active area; a first inorganic layer disposed on the substrate; a plurality of transistors disposed on the first inorganic layer in the active area; a second inorganic layer and a first organic layer disposed on the plurality of transistors; a plurality of patterns and a dam which are disposed to enclose the hole on the first inorganic layer in the first non-active area and formed by sequentially laminating the same or substantially same material as the second inorganic layer and the first organic layer; and a crack prevention unit which is disposed in the dam and is formed of the same or substantially same material as the first organic layer, in which the crack prevention unit is disposed on the substrate exposed from the first inorganic layer which is partially open.

Other detailed matters of the exemplary embodiments are included in the detailed description and the drawings.

According to the present disclosure, the propagation of the crack through an inorganic insulating layer when a hole is disposed in the active area may be reduced or minimized.

According to the present disclosure, the moisture permeation through a crack of an inorganic layer in the non-active area is reduced or minimized to improve a quality of the display device.

According to the present disclosure, the recognition of the crack prevention unit in the first non-active area disposed in the active area may be reduced or minimized.

The effects according to the present disclosure are not limited to the contents exemplified above, and more various effects are included in the present specification.

It is to be understood that both the foregoing general description and the following detailed description are exemplary and explanatory and are intended to provide further explanation of the inventive concepts as claimed.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and may be incorporated in and constitute a part of the disclosure, illustrate embodiments of the disclosure and together with the description serve to explain various principles of the disclosure. In the drawings:

FIG. 1 is a schematic plan view of a display device according to an exemplary embodiment of the present disclosure;

FIG. 2 is a cross-sectional view taken along the line I-I′ of FIG. 1 according to an embodiment of the present disclosure;

FIG. 3 is a cross-sectional view taken along the line II-II′ of FIG. 1 according to an embodiment of the present disclosure;

FIG. 4 is a view for explaining a moisture permeation path of a display device according to an exemplary embodiment of the present disclosure;

FIG. 5 is a schematic plan view of a display device according to another exemplary embodiment of the present disclosure; and

FIG. 6 is a schematic plan view of a display device according to yet another exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. Rather, the exemplary embodiments are provided by way of example only so that those skilled in the art can fully understand the disclosures of the present disclosure and the scope of the present disclosure. The scope of the present disclosure shall be defined by the appended Claims and their equivalents.

The shapes, sizes, areas, ratios, angles, numbers, and the like illustrated in the accompanying drawings for describing the various exemplary embodiments of the present disclosure are merely given by way of example. Therefore, the present disclosure is not limited thereto. Like reference numerals generally denote like elements throughout the specification. Further, in the following description of the present disclosure, a detailed explanation of known related technologies may be omitted or may be briefly provided to avoid unnecessarily obscuring the subject matter of the present disclosure. The terms such as ‘including’, ‘having’, “contain”, “constitute”, “make up of”, “formed of”, ‘consist of’ and any variations thereof used herein are generally intended to allow other components to be added unless the terms are used with the term ‘only’. Any references to singular may include plural unless expressly stated otherwise.

Any implementation described herein as an “example” is not necessarily to be construed as preferred or advantageous over other implementations.

In describing a time relationship, for example, when the temporal order is described as, for example, “after,” “subsequent,” “next,” and “before,” a case which is not continuous may be included unless a more limiting term, such as “just,” “immediate (ly),” or “direct (ly)” is used.

Components are interpreted to include an ordinary error range or tolerance range even if not expressly stated.

When the position relation between two parts is described using the terms such as ‘on’, ‘above’, ‘below’, ‘next’, “over”, “beside”, “beneath”, “near”, “close to”, “adjacent to”, “under”, one or more parts may be positioned between the two parts unless the terms are used the with term “just”, “close (ly), ‘immediately’ or ‘directly’. For example, when an element or layer is disposed “on” another element or layer, a third layer or element may be interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various embodiments of the present disclosure will be described in detail with reference to accompanying drawings.

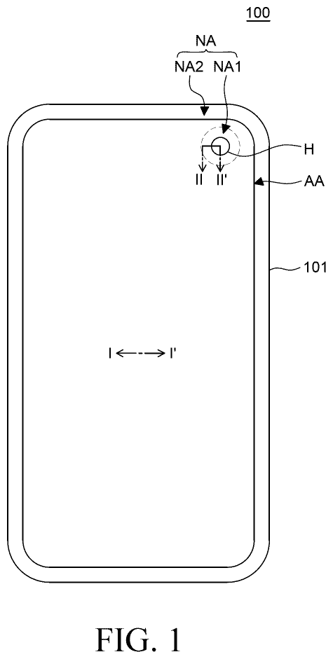

FIG. 1 is a schematic cross-sectional view of a display device according to an exemplary embodiment of the present disclosure. All the components of each display device according to all embodiments of the present disclosure are operatively coupled and configured.

Referring to FIG. 1, a display device 100 includes a substrate 101.

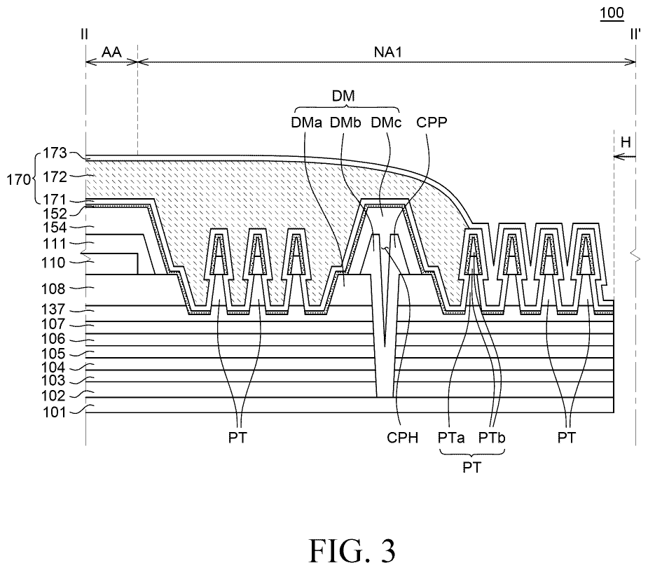

The substrate 101 may include a hole H disposed in an active area AA. The hole H may be a hole which passes through the substrate 101 and/or other components on the substrate 101. Further, the hole H may be disposed so as to correspond to a camera, a light sensor or other components. The hole H will be described below with reference to FIG. 3.

The substrate 101 includes an active area AA and a non-active area NA.

The active area AA is an area where images are displayed. In the active area AA, a plurality of sub pixels for displaying images and a pixel circuit for driving the plurality of sub pixels may be disposed. Each of the plurality of sub pixels is an individual unit which emits light, and a light emitting diode may be disposed in each of the plurality of sub pixels. The plurality of sub pixels may include a red sub pixel, a green sub pixel, a blue sub pixel. The plurality of sub pixels may further include a white sub pixel, but is not limited thereto. The colors of the sub pixels are not limited thereto. Sub pixels of other colors are also possible. The pixel circuit may include various transistors, storage capacitors, and/or wiring lines for driving the plurality of sub pixels. For example, the pixel circuit may be configured by various components, such as a driving transistor, a switching transistor, a sensing transistor, a storage capacitor, a gate line, and/or a data line, but is not limited thereto.

The non-active area NA is an area where no image is displayed. The non-active area NA includes a first non-active area NA1 and a second non-active area NA2.

The first non-active area NA1 may be disposed to enclose the hole H. It should be noted that, the term “enclose” here is not necessarily to be construed as fully enclosing the hole. On the contrary, the first non-active area NA1 may be disposed to fully or partially enclose the hole H, unless stated otherwise. In the first non-active area NA1, various wiring lines, such as a data line, a high potential power line, and/or a gate line, may be disposed. Various wiring lines disposed around the hole H detour the hole H to be electrically connected to the light emitting diode and the pixel circuit disposed at the left and right sides and/or upper and lower sides of the hole H or disposed to enclose the hole H. As illustrated in FIG. 1, one hole H may be provided, but it is not limited thereto, and various numbers of holes may be disposed in various positions. For example, one or two holes are disposed in the active area AA so that the camera is disposed in a first hole and various sensors, such as a distance sensing sensor or a face recognition sensor, may be disposed in a second hole.

The second non-active area NA2 may be disposed so as to enclose the active area AA. In the second non-active area NA2, various wiring lines and driving circuits for driving sub pixels disposed in the active area AA are disposed. For example, in the second non-active area NA2, a driving circuit, such as a gate driving circuit, data driving circuit, various wiring lines, or pads may be disposed, but is not limited thereto.

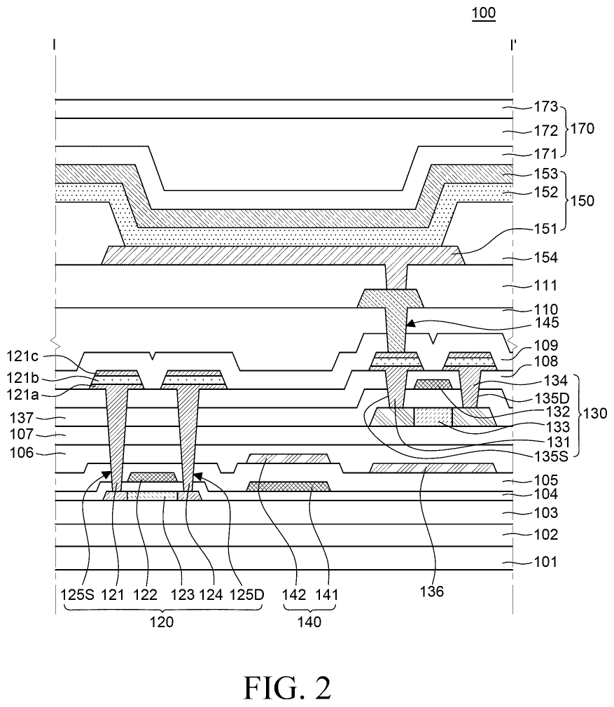

FIG. 2 is a cross-sectional view of one sub pixel of a display device taking along the line I-I′ of FIG. 1 according to an exemplary embodiment of the present disclosure.

Referring to FIG. 2, the display device 100 may include a substrate 101, a first transistor 120, a second transistor 130, a light emitting diode 150, and an encapsulation layer 170, but is not limited thereto, some components may be omitted or added if necessary.

The substrate 101 is a support member for supporting other components of the display device 100 and may be configured by an insulating material. For example, the substrate 101 may be formed of glass or resin. Further, the substrate 101 may be configured to include plastics such as polymer or polyimide (PI) or may be formed of a material having a flexibility.

When the substrate 101 is formed of polyimide, the substrate may be configured by two polyimides. An inorganic layer of silicon nitride (SiNx) or silicon oxide (SiOx) may be further disposed between two polyimides. But embodiments are not limited thereto. And the substrate may be configured by one or three or more polyimides.

A first buffer layer 102 is disposed on the substrate 101. The first buffer layer 102 may reduce permeation of moisture or impurities through the substrate 101. The first buffer layer 102 may be formed by a single layer of silicon nitride (SiNx) or silicon oxide (SiOx) or multiple layers thereof. But embodiments are not limited thereto. For example, the buffer layer 102 may be formed by a layer of other materials. When the first buffer layer 102 is formed of a plurality of layers, silicon oxide (Siox) and silicon nitride (SiNx) may be alternately formed. But embodiments are not limited thereto. For example, the first buffer layer 102 may be formed of a plurality of layers of the same or different materials. The first buffer layer 102 may be omitted depending on the type and material of the substrate 101, the structure and type of the thin-film transistor, and the like. A second buffer layer 103 is disposed on the first buffer layer 102. The second buffer layer 103 may protect the first transistor 120 and the second transistor 130 from impurities such as alkali ions leaked from the substrate 101. Furthermore, the second buffer layer 103 may enhance an adhesiveness between layers formed thereon and the substrate 101. The second buffer layer 103 may be configured by a single layer or a double layer of silicon oxide (Siox) or silicon nitride (SiNx), but is not limited thereto. In the meantime, the second buffer layer 103 may be omitted depending on the design.

The first transistor 120 is disposed on the second buffer layer 103. The first transistor 120 may include a first source electrode 121, a first gate electrode 122, a first semiconductor pattern 123, and a first drain electrode 124.

The first semiconductor pattern 123 may be formed of a polycrystalline semiconductor. For example, the polycrystalline semiconductor may be formed of a low temperature poly silicon (LTPS) having a high mobility, but is not limited thereto. When the semiconductor pattern is formed of a polycrystalline semiconductor or includes polycrystalline semiconductor, the energy consumption of the thin-film transistor is low and the reliability is excellent. The first semiconductor pattern 123 may include a channel region, a source region, and a drain region.

Alternatively, the first semiconductor pattern 123 may be formed of an oxide semiconductor. For example, the semiconductor pattern may be formed of any one of indium gallium zinc oxide (IGZO), indium zinc oxide (IZO), indium gallium tin oxide (IGTO), and indium gallium oxide (IGO), but is not limited thereto. When the first semiconductor pattern 123 is formed of an oxide semiconductor or includes an oxide semiconductor, it has an excellent effect to block the leakage current so that the luminance variation of the sub pixel (e.g., during the low speed driving) may be reduced or minimized.

A first gate insulating layer 104 is disposed in the entire area of the substrate 101 above the first semiconductor pattern 123. The first gate insulating layer 104 is disposed on the first semiconductor pattern 123 to insulate the first semiconductor pattern 123 and the first gate electrode 122 from each other. The first gate insulating layer 104 may include an insulating material such as silicon oxide (Siox) or silicon nitride (SiNx), other insulating inorganic material or an insulating organic material such as benzocyclobutene, an acrylic resin, an epoxy resin, a phenolic resin, a polyamide resin, and a polyimide resin.

The first gate electrode 122 is disposed on the first gate insulating layer 104. The first gate electrode 122 may be disposed so as to overlap the first semiconductor pattern 123. The first gate electrode 122 may be formed of a single layer or multiple layers formed of any one or more of molybdenum (Mo), aluminum (Al), chrome (Cr), gold (Au), titanium (Ti), nickel (Ni), neodymium (Nd), and copper (Cu), or an alloy thereof, but is not limited thereto.

A first interlayer insulating layer 105 is disposed on the first gate electrode 122. The first interlayer insulating layer 105 may include an insulating material.

When the first semiconductor pattern 123 may include a polycrystalline semiconductor, the first interlayer insulating layer 105 may include an inorganic layer having a content of hydrogen particles higher than that of a third interlayer insulating layer 108. For example, the first interlayer insulating layer 105 may include silicon nitride (SiNx) which is disposed by a deposition process using NH₃ gas. Accordingly, hydrogen particles included in the first interlayer insulating layer 105 are diffused into the polycrystalline semiconductor pattern during a hydrogenation process so that pores in the polycrystalline semiconductor pattern may be filled with hydrogen. Accordingly, the polycrystalline semiconductor pattern stabilizes to suppress the deterioration of the characteristic of the first transistor 120.

A light shielding layer 136 is disposed on the first interlayer insulating layer 105. The light shielding layer 136 may be configured by an opaque material, and particularly, by a conductive material, such as copper (Cu), aluminum (Al), molybdenum (Mo), nickel (Ni), titanium (Ti), chrome (Cr), or an alloy thereof, but it is not limited thereto. The light shielding layer 136 may be omitted depending on the design.

A second interlayer insulating layer 106 is disposed on the light shielding layer 136. The second interlayer insulating layer 106 may include an inorganic layer having a content of hydrogen particles higher than that of the third interlayer insulating layer 108, like the first interlayer insulating layer 105. For example, the second interlayer insulating layer 106 may include silicon nitride (SiNx) which is disposed by a deposition process using NH₃ gas, but is not limited thereto. The content of the hydrogen particles of the second interlayer insulating layer 106 may be the same as or different from that of the first interlayer insulating layer 105.

An third buffer layer 107 is disposed on the second interlayer insulating layer 106. The third buffer layer 107 may include a-Si, silicon nitride (SiNx), or silicon oxide (Siox), but is not limited thereto.

The second transistor 130 is disposed on the third buffer layer 107. The second transistor 130 may include a second source electrode 131, a second gate electrode 132, a second semiconductor pattern 133, and a second drain electrode 134.

The second semiconductor pattern 133 of the second transistor 130 may be disposed on the third buffer layer 107 so as to overlap the light shielding layer 136.

The second semiconductor pattern 133 of the second transistor 130 may include a polycrystalline semiconductor. For example, the polycrystalline semiconductor may include a low temperature poly silicon (LTPS) having a high mobility, but is not limited thereto. When the semiconductor pattern includes a polycrystalline semiconductor, the energy consumption the second transistor 130 is low and the reliability is excellent.

Alternatively, the second semiconductor pattern 133 may include an oxide semiconductor. For example, the second semiconductor pattern may include any one of indium gallium zinc oxide (IGZO), indium zinc oxide (IZO), indium gallium tin oxide (IGTO), and indium gallium oxide (IGO), but is not limited thereto. When the semiconductor pattern include an oxide semiconductor, it has an excellent effect to block the leakage current so that the luminance variation of the sub pixel (e.g., during the low speed driving) may be reduced or minimized.

A second gate insulating layer 137 is disposed on the second semiconductor pattern 133. The second gate insulating layer 137 may insulate the second gate electrode 132 and the second semiconductor pattern 133 from each other. The second gate insulating layer 137 may include an insulating material such as silicon oxide (SiOx) or silicon nitride (SiNx), other insulating inorganic material or an insulating organic material such as benzocyclobutene, an acrylic resin, an epoxy resin, a phenolic resin, a polyamide resin, and a polyimide resin.

The second gate electrode 132 is disposed on the second gate insulating layer 137. The second gate electrode 132 may include the same or substantially same material as the first gate electrode 122. For example, the second gate electrode 132 may be formed of a single layer or multiple layers formed of any one or more of molybdenum (Mo), aluminum (Al), chrome (Cr), gold (Au), titanium (Ti), nickel (Ni), neodymium (Nd), and copper (Cu), or an alloy thereof, but is not limited thereto.

The third interlayer insulating layer 108 is disposed on the second gate electrode 132. The third interlayer insulating layer 108 may be configured by silicon nitride (SiNx) or silicon oxide (Siox).

After disposing the third interlayer insulating layer 108, a first source contact hole 125S and a first drain contact hole 125D may be disposed so as to respectively correspond to the source region and the drain region of the first transistor 120. The first source contact hole 125S and the first drain contact hole 125D may be disposed to continuously pass through the first gate insulating layer 104 from the third interlayer insulating layer 108. A second source contact hole 135S and a second drain contact hole 135D may be disposed so as to respectively correspond to the source region and the drain region of the second transistor 130. The second source contact hole 135S and the second drain contact hole 135D may be disposed to continuously pass through the third interlayer insulating layer 108 and the second gate insulating layer 137.

The first source electrode 121, the first drain electrode 124, the second source electrode 131, and the second drain electrode 134 may be a single layer or multiple layers formed of any one or more of molybdenum (Mo), aluminum (Al), chrome (Cr), gold (Au), titanium (Ti), nickel (Ni), neodymium (Nd), and copper (Cu), or an alloy thereof, but are not limited thereto. The first source electrode 121, the first drain electrode 124, the second source electrode 131, and the second drain electrode 134 may be formed of a triple layered structure. For example, the first source electrode 121, the first drain electrode 124, the second source electrode 131 and the second drain electrode 134 may be configured by a first layer 121a, a second layer 121b, and a third layer 121c, but are not limited thereto.

The first source electrode 121 and the first drain electrode 124 of the first transistor 120, and the second source electrode 131 and the second drain electrode 134 of the second transistor 130 may be simultaneously disposed. By doing this, a number of processes of disposing source and drain electrodes of each of the first transistor 120 and the second transistor 130 may be reduced.

In the meantime, a storage capacitor 140 may be disposed between the first transistor 120 and the second transistor 130. As illustrated in FIG. 2, the storage capacitor 140 may include a first storage electrode 141 and a second storage electrode 142 which are disposed with the first interlayer insulating layer 105 therebetween.

The first storage electrode 141 is disposed on the first gate insulating layer 104. The first storage electrode 141 may be formed of the same or substantially same material on the same layer as the first gate electrode 122. For example, the first storage electrode 141 may include a single layer or multiple layers formed of any one or more of molybdenum (Mo), aluminum (Al), chrome (Cr), gold (Au), titanium (Ti), nickel (Ni), neodymium (Nd), and copper (Cu), or an alloy thereof, but is not limited thereto.

The second storage electrode 142 is disposed on the first interlayer insulating layer 105. The second storage electrode 142 may include the same or substantially same material on the same layer as the light shielding layer 136. For example, the second storage electrode 142 may be configured by a conductive material, such as copper (Cu), aluminum (Al), molybdenum (Mo), nickel (Ni), titanium (Ti), chrome (Cr), or an alloy thereof, but it is not limited thereto.

While the second storage electrode 142 is spaced apart from the light shielding layer 136 as illustrated in FIG. 2, the second storage electrode 142 may also be disposed integrally connected to the light shielding layer 136.

A passivation layer 109 is disposed on the first source electrode 121, the first drain electrode 124, the second source electrode 131, and the second drain electrode 134. The passivation layer 109 may include an inorganic insulating material, such as silicon nitride (SiNx) and silicon oxide (SiOx).

A first planarization layer 110 and a second planarization layer 111 are disposed on the passivation layer 109. The first planarization layer 110 and the second planarization layer 111 protect transistors disposed below the first planarization layer 110, and may mitigate or planarize a step difference caused by various patterns and electrodes. The first planarization layer 110 and the second planarization layer 111 may include an organic material, and for example, may be configured by a single layer or a double layer (or three or more layers) of polyimide or photo acryl, but are not limited thereto. Alternatively, in addition to the first planarization layer 110 and second planarization layer 111, more planarization layer may be disposed on the passivation layer 109.

The first planarization layer 110 may include a contact hole which electrically connects the second transistor 130 and a connection electrode 145. Specifically, the first planarization layer 110 may include a contact hole which exposes any one of the second source electrode 131 or the second drain electrode 134 of the second transistor 130.

The second planarization layer 111 may include a contact hole which electrically connects the connection electrode 145 and the anode electrode 151.

The connection electrode 145 is disposed between the first planarization layer 110 and the second planarization layer 111. The connection electrode 145 may connect the second source electrode 131 of the second transistor 130 and the anode electrode 151 of the light emitting diode 150. Even though in FIG. 2, it is illustrated that the connection electrode 145 is connected to the second source electrode 131, the connection electrode 145 may be connected to the second drain electrode 134. The connection electrode 145 may be configured by a conductive material, such as copper (Cu), aluminum (Al), molybdenum (Mo), nickel (Ni), titanium (Ti), chrome (Cr), or an alloy thereof, but is not limited thereto.

The light emitting diode 150 is disposed on the first transistor 120 and the second transistor 130. The light emitting diode 150 includes the anode electrode 151, an emission stack 152, and a cathode electrode 153.

In the meantime, the display device 100 may be implemented by a top emission type or a bottom emission type. In the case of the top emission type, a reflective layer which reflects light emitted from the emission stack 152 toward the cathode electrode 153 may be disposed below the anode electrode 151. For example, the reflective layer may include a material having an excellent reflectivity, such as aluminum (Al), or silver (Ag), molybdenum (Mo), tungsten (W), chromium (Cr), or alloys thereof, but is not limited thereto. For example, the anode 151 may have a three-layer structure of Ag/Pd/Cu, but is not limited thereto. Alternatively, the anode 410 may further include a transparent conductive material layer having a high work function such as indium-tin-oxide (ITO).

In the case of the bottom emission type, the anode electrode 151 may be formed only by a transparent conductive material allowing light to pass therethrough. For example, the anode 151 may be formed of at least one of indium-tin-oxide (ITO) and indium zinc oxide (IZO). Hereinafter, the description will be made under the assumption that the display device 100 according to the exemplary embodiment of the present specification is a top emission type.

The anode electrode 151 is disposed on the second planarization layer 111. The anode electrode 151 may correspond to each of the plurality of sub pixels. That is, the anode electrode 151 may be patterned so as to correspond to each of the plurality of sub pixels one by one. The anode electrode 151 may be electrically connected to the connection electrode 145 and the second source electrode 131 of the second transistor 130 through contact holes disposed in the second planarization layer 111 and the first planarization layer 110.

The anode electrode 151 may be formed of a conductive material having a high work function to supply holes to the emission stack 152. For example, the anode electrode 151 may be disposed with a transparent conductive material such as indium tin oxide (ITO) and indium zinc oxide (IZO), but is not limited thereto.

A bank 154 is disposed on the anode electrode 151 and the second planarization layer 111. The bank 154 may be disposed on the second planarization layer 111 so as to cover an edge of the anode electrode 151.

The bank 154 is an insulating layer disposed between the plurality of sub pixels to divide the plurality of sub pixels. The bank 154 may include an organic insulating material or inorganic insulating material. For example, the bank 154 may be formed of at least one or more materials among inorganic insulating materials, such as silicon nitride (SiNx) or silicon oxide (Siox), organic insulating materials, such as benzocyclobutene (BCB), acryl resin, epoxy resin, phenolic resin, polyamide resin, or polyimide resin, or photosensitizers including a black pigment, but is not limited thereto.

The bank 154 may be formed to be transparent or black or colored. The bank 154 may be disposed to cover an end of the anode electrode 151.

At least one spacer may be disposed on the bank 154 to reduce or prevent the light emitting diode 150 from being damaged and reduce or minimize the fracture of the display device 100 due to external impact. The emission stack 152 is disposed on the anode electrode 151 and the bank 154. The emission stack 152 may be disposed over the entire surface of the substrate 101. The emission stack 152 may be an organic layer to emit a specific color. The emission stack 152 may include a light emitting layer. The light emitting layer may be disposed so as to correspond to each of the plurality of sub pixels SP. The emission stack 152 may further include at least one of various layers, such as a hole transport layer, a hole injection layer, a hole blocking layer, an electron injection layer, an electron blocking layer, or an electron transport layer above or below the light emitting layer. The hole transport layer, the hole injection layer, the hole blocking layer, the electron injection layer, the electron blocking layer, and the electron transport layer may be common layers commonly formed in the plurality of sub pixels. But embodiments are not limited thereto. For example, the hole transport layer, the hole injection layer, the hole blocking layer, the electron injection layer, the electron blocking layer, and the electron transport layer may be disposed so as to correspond to each of the plurality of sub pixels SP.

In a tandem structure in which the plurality of light emitting layers overlaps, a charge generation layer may be further disposed between the light emitting layers.

The light emitting layer may be individually disposed in every sub pixel to emit different color light for each sub pixel. For example, a red light emitting layer, a green light emitting layer, and a blue light emitting may be individually disposed in every sub pixel. Alternatively, a common light emitting layer is disposed to emit white light without distinguishing colors for every pixel and a color filter which distinguishes colors may be further provided.

The cathode electrode 153 is disposed on the emission stack 152 and the bank 154. The cathode electrode 153 may be disposed over the entire surface of the substrate 101 as one layer. That is, the cathode electrode 153 may be a common layer which is commonly disposed in the plurality of sub pixels. The cathode electrode 153 supplies electrons to the emission stack 152 so that the cathode electrode may be formed of a conductive material having a low work function. For example, the cathode electrode 153 may be disposed with a transparent conductive material such as indium tin oxide (ITO) or indium zinc oxide (IZO), or a metal alloy such as MgAg or a ytterbium (Yb) alloy, and/or may further include a metal doped layer, but is not limited thereto.

The encapsulation layer 170 is disposed on the light emitting diode 150. The encapsulation layer 170 protects the light emitting diode 150 from moisture permeating from the outside of the display device 100. The encapsulation layer 170 includes a first inorganic encapsulation layer 171, an organic encapsulation layer 172, and a second inorganic encapsulation layer 173.

The first inorganic encapsulation layer 171 is disposed on the cathode electrode 153 to suppress the permeation of the moisture or oxygen. The first inorganic encapsulation layer 171 may be formed of an inorganic material, such as silicon oxide (SiOx), silicon nitride (SiNx), silicon oxy nitride (SiNxOy), or aluminum oxide (AlyOz), but is not limited thereto.

The organic encapsulation layer 172 is disposed on the first inorganic encapsulation layer 171 to planarize the surface thereof. Further, the organic encapsulation layer 172 may cover foreign materials or particles which may be generated during a manufacturing process. The organic encapsulation layer 172 may be formed of an organic material, such as silicon oxy carbon (SiOxCz), acryl or epoxy resin, but is not limited thereto.

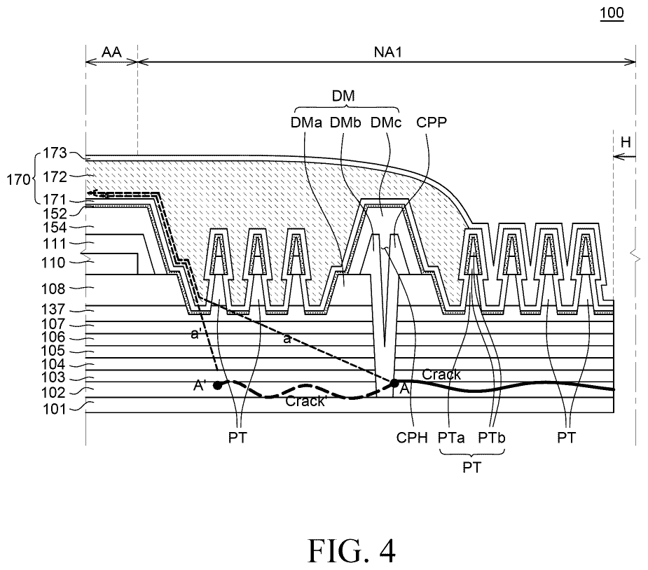

The organic encapsulation layer 172 may include a first organic encapsulation layer disposed in the active area AA, a second organic encapsulation layer disposed to be between the first organic encapsulation layer and the hole H, and a third organic encapsulation layer disposed to be between the first organic encapsulation layer and the second non-active area NA2. The organic encapsulation layer 172 will be described below in detail with reference to FIGS. 3 and 4.

The second inorganic encapsulation layer 173 is disposed on the organic encapsulation layer 172 and may suppress the permeation of the moisture or oxygen, like the first inorganic encapsulation layer 171. At this time, the second inorganic encapsulation layer 173 and the first inorganic encapsulation layer 171 may be disposed to seal the organic encapsulation layer 172. Accordingly, the moisture or oxygen permeating the light emitting diode 150 may be effectively reduced or prevented by the second inorganic encapsulation layer 173. The second encapsulation layer 173 may be formed of an inorganic material, such as silicon oxide (Siox), silicon nitride (SiNx), silicon oxy nitride (SiNxOy), or aluminum oxide (AlyOz), but is not limited thereto.

Hereinafter, a first non-active area NA1 of a display device 100 according to an exemplary embodiment of the present disclosure will be described with reference to FIG. 3.

FIG. 3 is a cross-sectional view taken along the line II-II′ of FIG. 1 according to an exemplary embodiment of the present disclosure. FIG. 3 is a schematic cross-sectional view of a first non-active area NA1 adjacent to a hole H according to an exemplary embodiment of the present disclosure.

Referring to FIG. 3, a hole H is disposed in the first non-active area NA1. In a position corresponding to the hole H, a camera may be disposed below the substrate 101, but is not limited thereto, and a photo sensor or other components may be disposed in the hole H. The hole H allows light to be easily transmitted from the upper portion of the hole H (e.g., the camera or the photo sensor).

Referring to FIG. 3, a dam DM, a plurality of patterns PT, and an encapsulation layer 170 are disposed in the first non-active area NA1.

The dam DM may be disposed between the hole H and the active area AA.

The dam DM is disposed so as to enclose the hole H. The dam DM may be disposed in a closed curve shape enclosing the outer periphery of the hole H. The dam DM may suppress overflowing of the organic encapsulation layer 172 to flow to the hole H.

The dam DM includes a first sub dam DMa, a second sub dam DMb, and a third sub dam DMc.

For example, the first sub dam DMa may be formed of an inorganic layer. The first sub dam DMa may be formed of the same or substantially same material as the third interlayer insulating layer 108 and/or the second gate insulating layer 137. The second sub dam DMb and the third sub dam DMc may be formed of an organic layer. The second sub dam DMb may be formed of the same or substantially same material as the first planarization layer 110 and/or the second planarization layer 111. The third sub dam DMc may be disposed with the same or substantially same material as the bank 154, simultaneously. However, a material of the insulating layer of the dam DM and a number of layers are not limited thereto.

A crack prevention unit (separation element) CPP is disposed in the dam DM. The crack prevention unit CPP will be described in more detail with reference to FIG. 4. Although the crack prevention unit is described as an example in most of the specification, it is merely an example for the separation element, which at least partially separates (disconnects) at least one inorganic layer.

At least one of the insulating layers disposed below the dam DM may be opened. For example, insulating layers disposed below the dam DM may be opened to expose the substrate 101. The crack prevention unit CPP may be disposed in an open area of the insulating layers. For example, the crack prevention unit CPP may be disposed on the substrate 101 which is exposed from the opened insulating layers. The insulating layers disposed below the dam DM may have a disconnected structure by the crack prevention unit CPP. Specifically, the crack prevention unit CPP may be disposed to have a structure to disconnect at least one of or all of the inorganic layers, such as a buffer layer 102, the second buffer layer 103, the first gate insulating layer 104, the first interlayer insulating layer 105, the third buffer layer 107, the second gate insulating layer 137, and the third interlayer insulating layer 108, disposed below the dam DM.

In the dam DM, the crack prevention unit CPP may be disposed on the same layer as the second sub dam DMb and may be formed of the same or substantially same material as the second sub dam DMb. That is, the crack prevention unit CPP may be defined as a second sub dam DMb. However, the crack prevention unit CPP may be disposed with a separate configuration from the second sub dam DMb, but is not limited thereto.

The crack prevention unit CPP disposed in the dam DM may be disposed in a closed curve shape enclosing the outer periphery of the hole H. Accordingly, at least one of or all of the inorganic layers, such as the buffer layer 102, the second buffer layer 103, the first gate insulating layer 104, the first interlayer insulating layer 105, the second interlayer insulating layer 106, the third buffer layer 107, the second gate insulating layer 137, and the third interlayer insulating layer 108 may be disposed to have a disconnected structure with respect to the crack prevention unit CPP.

In the meantime, in order to disconnect the inorganic layers disposed below the dam DM, the crack prevention unit CPP is disposed in an open area of the inorganic layers which, for example, may be open to expose the substrate 101. Accordingly, the crack prevention unit CPP may have a portion extending onto the substrate 101, and a concave portion CPH corresponding to a shape of a part of the crack prevention unit CPP extending onto the substrate 101 may be formed on an upper surface of the crack prevention unit CPP.

The plurality of patterns PT is disposed between the hole H and the dam DM and/or between the dam DM and the active area AA. The plurality of patterns PT is disposed between the hole H and the dam DM and between the dam DM and the active area AA, in plurality, respectively. At this time, the plurality of patterns PT may be disposed to be spaced apart from each other. The plurality of patterns PT may be disposed in a closed curve shape enclosing the outer periphery of the hole H.

The plurality of patterns PT includes a first sub pattern PTa and a second sub pattern PTb. The first sub pattern PTa may be formed of an inorganic layer. For example, the first sub pattern PTa may be formed of the same or substantially same material as the third interlayer insulating layer 108 and/or the second gate insulating layer 137. The second sub pattern PTb may be formed of an organic layer. For example, the second sub pattern PTb may be formed of the same or substantially same material as the first planarization layer 110 and/or the second planarization layer 111, but a material which configures the plurality of patterns PT and a number of layers are not limited thereto.

The plurality of patterns PT may suppress the moisture from permeating into the active area AA through the emission stack 152. That is, the emission stack 152 which is vulnerable to the moisture permeation may have a disconnection structure by the plurality of patterns PT. Specifically, a cross-sectional shape of the first sub pattern PTa and the second sub pattern PTb of the plurality of patterns PT has a tapered trapezoidal shape, and an upper surface of the second sub pattern PTb may have a smaller width than that of a lower surface of the first sub pattern PTa. In the meantime, a cross-sectional shape of the first sub pattern PTa and the second sub pattern PTb may have an inversely tapered trapezoidal shape, and a shape of the plurality of patterns PT for disconnection is not limited thereto.

In the meantime, some organic layers of the emission stack 152 of the light emitting diode 150, for example, a hole transport layer, a hole injection layer, a hole blocking layer, an electron injection layer, an electron blocking layer, and an electron transport layer and a cathode electrode 153 are common layers. The organic layers are disposed to extend from the active area AA to the hole H of the first non-active area. Accordingly, some organic layers of the emission stack 152 or the cathode electrode 153 disposed above the plurality of patterns PT are not continuous, but may be disconnected due to the plurality of patterns PT.

Accordingly, even though the moisture permeates through the emission stack 152, the disconnected structure of the emission stack 152 may suppress the permeated moisture from moving to the active area AA.

Referring to FIG. 3, the first inorganic encapsulation layer 171 is disposed in the first non-active area NA1. The first inorganic encapsulation layer 171 may extend from the active area AA to the first non-active area NA1. For example, the first inorganic encapsulation layer 171 may extend from the active area AA up to the hole H. At this time, the first inorganic encapsulation layer 171 may cover an upper surface and a side surface of the dam DM, and upper surfaces and side surfaces of the plurality of patterns PT in the first non-active area NA1.

The organic encapsulation layer 172 is disposed on the first inorganic encapsulation layer 171 in the first non-active area NA1.

The organic encapsulation layer 172 is disposed in the active area AA and a part of the first non-active area NA1 extending from the active area AA.

A part of an upper surface of the organic encapsulation layer 172 disposed in the first non-active area NA1 may be disposed to be lower than upper surfaces of the plurality of dams DM.

The organic encapsulation layer 172 may be disposed to be filled between the plurality of patterns PT. The organic encapsulation layer 172 may be disposed to be spaced apart from each other between the plurality of patterns PT, but is not limited thereto and the organic encapsulation layer 172 may be disposed to be connected between the plurality of patterns PT.

In an area adjacent to the hole H, the first inorganic encapsulation layer 171 and the second inorganic encapsulation layer 173 may be in contact with each other. In the meantime, the second inorganic encapsulation layer 173 may cover a part of an upper surface of the first inorganic encapsulation layer 171 which is exposed from the organic encapsulation layer 172. First, on the dam DM, the first inorganic encapsulation layer 171 may overlap with the second inorganic encapsulation layer 173 with the organic encapsulation layer 172 interposed therebetween. Further, on the plurality of patterns PT adjacent to the hole H, the first inorganic encapsulation layer 171 may be in contact with the second inorganic encapsulation layer 173. By doing this, the first inorganic encapsulation layer 171 and the second inorganic encapsulation layer 173 may seal the organic encapsulation layer 172.

When an upper surface of the organic encapsulation layer 172 is disposed to be lower than the upper surfaces of the plurality of patterns PT, the second inorganic encapsulation layer 173 may be in contact with the first inorganic encapsulation layer 171 in an area overlapping side surfaces of the plurality of patterns PT disposed in the first non-active area NA1.

FIG. 4 is a view for explaining a moisture permeation path of a display device according to an exemplary embodiment of the present disclosure. In FIG. 4, Crack, A, and a denote a crack generated when a hole H of the display device 100 according to the exemplary embodiment of the present disclosure is disposed, a moisture permeation start point, and a moisture permeation path, respectively. Crack′, A′, and a′ denote a crack generated when a hole of the display device according to a comparative example is disposed, a moisture permeation start point, and a moisture permeation path, respectively. At this time, the display device according to the comparative example refers to a display device which does not include a crack prevention unit.

When a hole is disposed to pass through the substrate and the other components on the substrate to dispose a component such as a camera or a photo sensor in an active area of the display device, Crack′ may be caused in the substrate and the other components on the substrate, due to the stress generated when the hole is disposed. Specifically, in the inorganic layers formed of an inorganic material which is vulnerable to the stress, a probability of cracks caused when the hole is disposed may be higher. Further, an end of the inorganic layer which is exposed to the outside by the Crack′ may serve as a start point A′ of the moisture permeation. Accordingly, the moisture permeation is generated from the start point A′ of the moisture permeation to the active area, and a quality of the display device is degraded. At this time, the longer the distance along which the crack Crack′ is generated, that is, the closer the position of the moisture permeation start point A′ to the active area, the shorter the moisture permeation path a′ through which the moisture permeation reaches the active area. The longer the distance along which the crack Crack′ is generated, the easier the moisture permeation occurs in the active area and the worse the quality of the display device.

Referring to FIG. 4, in the display device according to the comparative example, the crack prevention unit is not disposed in the first non-active area. Therefore, the crack Crack′ may be generated even in the position adjacent to the active area due to the stress generated when the hole is disposed. At this time, the start point A′ of the moisture permeation is generated in a position adjacent to the active area so that the permeation path a′ through which the moisture permeation reaches the active area is shortened and the probability of moisture permeation in the active area is increased.

In the display device 100 according to the exemplary embodiment of the present disclosure, the crack prevention unit CPP is disposed in the first non-active area NA1 to disconnect at least one of or all of the inorganic layers which are formed of inorganic materials vulnerable to the stress. Therefore, even though the crack is caused by the stress generated when the hole H is disposed, the crack may not propagate to the inside of the crack prevention unit CPP. Accordingly, the start point A of the moisture permeation is also disposed at the outside of the crack prevention unit CPP to be disposed in a position which is not adjacent to the active area AA. Further, the moisture permeation path a through which the moisture permeation reaches the active area AA also extends to the outside of the crack prevention unit CPP so that the moisture permeation to the active area AA may be minimized.

In the display device 100 according to the exemplary embodiment of the present disclosure, the crack prevention unit CPP is disposed in the first non-active area NA1 to reduce or minimize the propagation of the crack through the inorganic layer when the hole H is disposed in the active area AA.

Specifically, in the display device 100 according to the exemplary embodiment of the present disclosure, in the first non-active area NA1, at least one of the insulating layers disposed below the dam DM are open, for example, to expose the substrate 101, and the crack prevention unit CPP is disposed in open areas of the insulating layers. Accordingly, the crack prevention unit CPP may disconnect at least one of the inorganic layers formed of inorganic materials which are vulnerable to the stress, among the insulating layers, in the non-active area NA1. Accordingly, even though the crack is caused by the stress generated when the hole H is disposed, the inorganic layers are disconnected so that the crack does not or less propagate to the inside of the crack prevention unit CPP. Further, when the hole H is disposed in the active area AA, the propagation of the crack through the inorganic layer may be reduced or minimized. Accordingly, in the display device 100 according to the exemplary embodiment of the present disclosure, the crack prevention unit CPP is disposed in the first non-active area NA1 to reduce or minimize the propagation of the crack through the inorganic layer when the hole H is disposed in the active area AA.

In the display device 100 according to the exemplary embodiment of the present disclosure, when the hole H is disposed in the active area AA, the propagation of the crack through the inorganic layer is reduced minimized to reduce or minimize the moisture permeation into the active area AA.

Specifically, in the display device 100 according to the exemplary embodiment of the present disclosure, the crack prevention unit CPP may be disposed in the first non-active area NA1 to reduce or minimize the propagation of the crack through the inorganic layer when the hole H is disposed in the active area AA. Accordingly, an end of the inorganic layer which is exposed to the outside due to the crack which is a start point A of the moisture permeation is disposed so as not to be adjacent to the active area AA. Therefore, the moisture permeation path A through which the moisture permeation reaches the active area AA is extended, and the moisture permeation to the active area AA may be reduced or minimized. Accordingly, in the display device 100 according to the exemplary embodiment of the present disclosure, when the hole H is disposed in the active area AA, the propagation of the crack through the inorganic layer is reduced or minimized to reduce or minimize the moisture permeation into the active area AA and improve a quality of the display device.

In the display device 100 according to the exemplary embodiment of the present disclosure, the crack prevention unit CPP is disposed in the dam DM to reduce or minimize the recognition of the crack prevention unit CPP from the first non-active area NA1 disposed in the active area AA.

Specifically, the crack prevention unit is disposed to disconnect the inorganic layers in the first non-active area so as to downwardly extend so that an upper surface of the crack prevention unit may be disposed with a seam shape which is downwardly recessed. Further, the first non-active area in which the crack prevention unit is disposed is configured to be disposed in the active area so that there may be a limitation or problem in that the seam shape of the upper surface of the crack prevention unit is visible in the first non-active area.

Accordingly, in the display device 100 according to the exemplary embodiment of the present disclosure, the crack prevention unit CPP is disposed on the same or substantially same layer as the second sub dam DMb disposed between the first sub dam DMa and the third sub dam DMc in a laminated structure of the dam DM. Therefore, the crack prevention unit CPP may be disposed in the dam DM. The third sub dam DMc is formed of an organic material so that even though the upper surface of the crack prevention unit CPP is not even, the upper surface of the dam DM may be configured to be a flat shape by the third sub dam DMc formed of the organic material. Therefore, the crack prevention unit CPP may disconnect the inorganic layer of the first non-active area NA1 without limiting a shape, and the recognition of the crack prevention unit CPP from the first non-active area NA1 may be reduced or minimized. As a result, in the display device 100 according to the exemplary embodiment of the present disclosure, the crack prevention unit CPP is disposed in the dam DM to reduce or minimize the recognition of the crack prevention unit CPP from the first non-active area NA1 disposed in the active area AA1. Further, the display quality of the display device 100 may be improved.

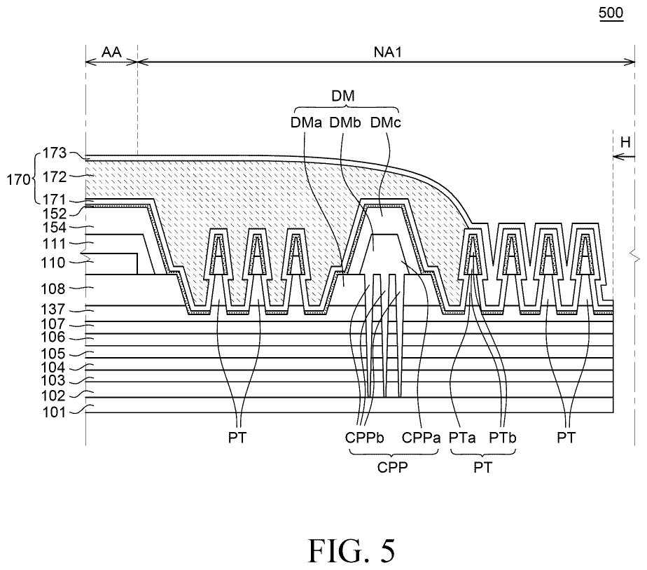

FIG. 5 is a schematic plan view of a display device according to another exemplary embodiment of the present disclosure. The only difference between a display device 500 of FIG. 5 and the display device 100 of FIGS. 1 to 4 is a shape of a crack prevention unit CPP, but the other configuration is substantially the same, so that a redundant description will be omitted or may be briefly provided.

Referring to FIG. 5, the crack prevention unit CPP includes a first part CPPa and a second part CPPb.

The first part CPPa of the crack prevention unit CPP is a part of the crack prevention unit CPP disposed on the first sub dam DMa. That is, the first part CPPa is disposed on the first sub dam DMa, and an upper surface and a side surface of the first part CPPa may be disposed to be covered by the third sub dam DMc.

The second part CPPb of the crack prevention unit CPP is a part of the crack prevention unit CPP disposed in open areas of at least one of or all of the inorganic layers disposed below the dam DM and the first sub dam DMa. As an example, the second part CPPb of the crack prevention unit CPP may be disposed to be in contact with the substrate 101.

The crack prevention unit CPP may comprise at least one second part CPPb. For example, the second part CPPb of the crack prevention unit CPP may be disposed in plurality. That is, the crack prevention unit CPP may have a shape in which a plurality of second parts CPPb is disposed below the first part CPPa. By doing this, the crack prevention unit CPP may further reduce or minimize the propagation of the crack. At this time, even though in FIG. 5, it is illustrated that three second parts CPPb are disposed in the crack prevention unit CPP, the number of the second parts CPPb of the crack prevention unit CPP is not limited thereto.

In the display device 500 according to another exemplary embodiment of the present disclosure, the crack prevention unit CPP is disposed in the first non-active area NA1 to further reduce or minimize the propagation of the crack through the inorganic layer when the hole H is disposed in the active area AA.

Specifically, in the display device 500 according to another exemplary embodiment of the present disclosure, in the first non-active area NA1, the insulating layers disposed below the dam DM are open to expose the substrate 101 and the crack prevention unit CPP is disposed in open areas of the insulating layers. Accordingly, the crack prevention unit CPP may disconnect the inorganic layers formed of inorganic materials which are vulnerable to the stress, among the insulating layers, in the non-active area NA1. Accordingly, even though the crack is caused by the stress generated when the hole H is disposed, the inorganic layers are disconnected so that the crack may not propagate to the inside of the crack prevention unit CPP. Further, when the hole H is disposed in the active area AA, the propagation of the crack through the inorganic layer may be reduced or minimized. Further, as an example, a plurality of second parts CPPb disposed in the area in which the inorganic layers disposed below the dam DM and the first sub dam DMa are open may be disposed in the crack prevention unit CPP so that the inorganic layers may be disconnected multiple times. Accordingly, the propagation of the crack through the inorganic layers when the hole H is disposed in the active area AA may be further reduced or minimized. Accordingly, in the display device 500 according to another exemplary embodiment of the present disclosure, the crack prevention unit CPP is disposed in the first non-active area NA1 to further reduce or minimize the propagation of the crack through the inorganic layer when the hole H is disposed in the active area AA.

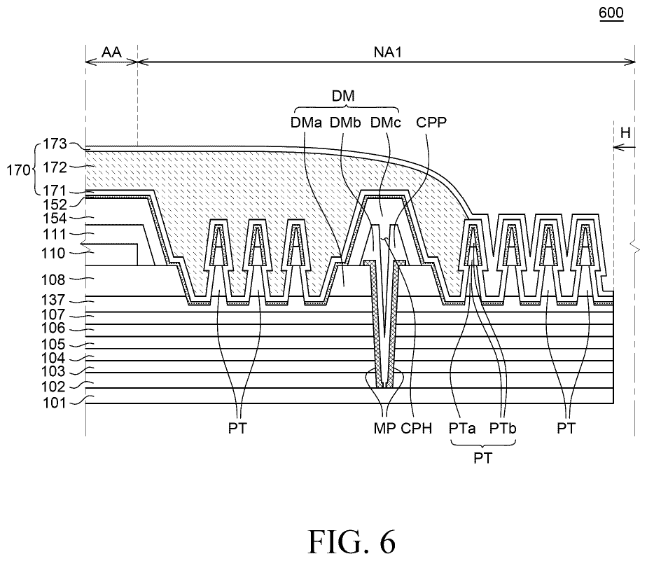

FIG. 6 is a schematic plan view of a display device according to yet another exemplary embodiment of the present disclosure. The only difference between a display device 600 of FIG. 6 and the display device 100 of FIGS. 1 to 4 is a shape of a crack prevention unit CPP, but the other configuration is substantially the same, so that a redundant description will be omitted or may be briefly provided.

Referring to FIG. 6, at least one pattern MP may be disposed on a side surface of the crack prevention unit CPP. The at least one pattern MP is disposed between an area in which the inorganic layers are open by the crack prevention unit CPP and the crack prevention unit CPP. As an example, the at least one pattern MP may be in contact with a part of the upper surface of the substrate 101, side surfaces of the open inorganic layers, a side surface and a part of an upper surface of the first sub dam DMa.

The at least one pattern may be formed in plurality. For example, a plurality of patterns MP may be spaced apart from each other. That is, some of the plurality of patterns MP is disposed between the crack prevention unit CPP and the active area AA, and the others of the plurality of patterns MP may be disposed between the crack prevention unit CPP and the hole H.

The at least one pattern MP may be formed of various materials. For example, the at least one pattern MP may be formed of various metal materials and alloys, and for example, may be formed of the same or substantially same material as the second gate electrode 132 of the second transistor 130 of the active area AA, but is not limited thereto.

In the display device 600 according to yet another exemplary embodiment of the present disclosure, the at least one pattern MP is disposed on the side surface of the crack prevention unit CPP so that the propagation of the crack through the inorganic layer when the hole H is disposed in the active area AA may be further reduced or minimized.

Specifically, in the display device 600 according to yet another exemplary embodiment of the present disclosure, in the first non-active area NA1, the insulating layers disposed below the dam DM are open to, for example, expose the substrate 101, and the crack prevention unit CPP is disposed in open areas of the insulating layers to, for example, contact the substrate 101. Accordingly, the crack prevention unit CPP may disconnect at least one of or all of the inorganic layers formed of inorganic materials which are vulnerable to the stress, among the insulating layers, in the non-active area NA1. The at least one pattern MP is disposed on the side surfaces of the crack prevention unit CPP to further reduce or minimize the crack from propagating to the inside of the crack prevention unit CPP. Further, the at least one pattern MP is disposed to be spaced apart from each other so that the crack prevention unit CPP formed of an organic material is disposed in a space formed by the at least one pattern MP. Therefore, the crack generated when the hole H is disposed may be further mitigated while passing through one pattern MP, the crack prevention unit CPP, and the other pattern MP. Accordingly, the crack caused by the stress generated when the hole H is disposed may not propagate to the inside of the crack prevention unit CPP and the at least one pattern MP, and the propagation of the crack through the inorganic layer when the hole H is disposed in the active area AA may be further reduced or minimized. Accordingly, in the display device 600 according to yet another exemplary embodiment of the present disclosure, the crack prevention unit CPP is disposed in the first non-active area NA1 to further reduce or minimize the propagation of the crack through the inorganic layer when the hole H is disposed in the active area AA.

The exemplary embodiments of the present disclosure can also be described as follows:

According to an aspect of the present disclosure, a display device may comprise a substrate including a first non-active area in which a hole is disposed, an active area which encloses the first non-active area, and a second non-active area which encloses the active area; a first inorganic layer disposed on the substrate; a plurality of patterns and a dam disposed to enclose the hole on the first inorganic layer of the first non-active area; and a crack prevention unit which is disposed in the dam and is disposed on the substrate exposed from the first inorganic layer which is partially open.

The display device may further comprise a second inorganic layer disposed on the first inorganic layer, and a first organic layer and a second organic layer disposed on the second inorganic layer, wherein the dam includes: a first sub dam formed of the same or substantially same material as the second inorganic layer; a second sub dam formed of the same or substantially same material as the first organic layer; and a third sub dam formed of the same or substantially same material as the second organic layer, and the crack prevention unit is the second sub dam.

The crack prevention unit may include a first part disposed on the first sub dam; and a second part which is disposed in a part in which the first inorganic layer and the first sub dam are at least partially open.

The crack prevention unit may include a plurality of second parts.

The display device may further comprise a pattern disposed on a side surface of the crack prevention unit.

The pattern may be in contact with a part of an upper surface of the substrate, a side surface of the first inorganic layer, a side surface and a part of the upper surface of the first sub dam.

The pattern may be disposed in plural and the plurality of patterns may be spaced apart from each other.

The pattern may be formed of the same or substantially same material as gate electrodes of a plurality of transistors disposed in the active area.

The plurality of patterns may be disposed between the hole and the dam and between the dam and the active area, in plurality, respectively.

According to another aspect of the present disclosure, a display device may comprise a substrate including a first non-active area in which a hole is disposed, an active area which encloses the first non-active area, and a second non-active area which encloses the active area; a first inorganic layer disposed on the substrate; a plurality of transistors disposed on the first inorganic layer in the active area; a second inorganic layer and a first organic layer disposed on the plurality of transistors; a plurality of patterns and a dam which are disposed to enclose the hole on the first inorganic layer in the first non-active area and formed by sequentially laminating the same or substantially same material as the second inorganic layer and the first organic layer; and a crack prevention unit which is disposed in the dam and is formed of the same or substantially same material as the first organic layer.

The crack prevention unit may be disposed on the substrate exposed from the first inorganic layer which is partially open.

The dam may include a first sub dam formed of the same or substantially same material as the second inorganic layer; a second sub dam formed of the same or substantially same material as the first organic layer; and a third sub dam disposed on the second sub dam, and the crack prevention unit may be the second sub dam.

The crack prevention unit may include a first part disposed on the first sub dam; and a second part which is disposed in a part in which the first inorganic layer and the first sub dam are at least partially open.

The crack prevention unit may include a plurality of second parts.

The display device may further comprise a pattern disposed between an area in which the first inorganic layer and the second inorganic layer are open and the crack prevention unit.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including a first non-active area in which a hole is disposed, and an active area adjacent to the first non-active area;
a first inorganic layer disposed on the substrate; and
a separation element which is disposed adjacent to the hole in an open area of the first inorganic layer which is partially open in the first non-active area.

2. The display device according to claim 1, further comprising a dam disposed adjacent to the hole on the first inorganic layer of the first non-active area,
wherein the separation element is disposed in the dam.

3. The display device according to claim 2, further comprising:
a second inorganic layer disposed on the first inorganic layer, and a first organic layer and a second organic layer disposed on the second inorganic layer,
wherein the dam includes:
a first sub dam formed of the same material as the second inorganic layer;
a second sub dam formed of the same material as the first organic layer; and
a third sub dam formed of the same material as the second organic layer, and
the separation element is the second sub dam.

4. The display device according to claim 3, wherein an upper surface and a portion of a side surface of the separation element are disposed to be covered by the third sub dam.

5. The display device according to claim 3, wherein a concave portion corresponding to a shape of a part of the separation element extending in the first inorganic layer is formed on an upper surface of the separation element, and is covered by the third sub dam.

6. The display device according to claim 3, wherein the separation element includes:
a first part disposed on the first sub dam; and
a second part which is disposed in a part in which the first inorganic layer and the first sub dam are at least partially open.

7. The display device according to claim 6, wherein the separation element includes a plurality of second parts.

8. The display device according to claim 1, further comprising:
a pattern disposed on a side surface of the separation element.

9. The display device according to claim 3, further comprising a pattern disposed on a side surface of the separation element,
wherein the pattern is in contact with a part of an upper surface of the substrate, a side surface of the first inorganic layer, a side surface and a part of the upper surface of the first sub dam.

10. The display device according to claim 8, wherein the pattern is disposed as a plurality of patterns spaced apart from each other.

11. The display device according to claim 8, wherein the pattern is formed of the same material as gate electrodes of a transistor disposed in the active area.

12. The display device according to claim 1, further comprising a plurality of second patterns disposed to enclose the hole on the first inorganic layer of the first non-active area,
wherein the plurality of second patterns is disposed between the hole and the separation element and between the separation element and the active area, in plurality, respectively.

13. The display device according to claim 2, wherein the active area is configured to enclose the first non-active area, and the dam is configured to enclose the hole.

14. The display device according to claim 1, wherein the separation element is disposed on the substrate exposed from the first inorganic layer.

15. The display device according to claim 1, wherein the first inorganic layer comprises at least one of a buffer layer, a first gate insulating layer and a first interlayer insulating layer of a first transistor disposed in the active area, an upper buffer layer, a second gate insulating layer and a second interlayer insulating layer of a second transistor disposed in the active area.

16. The display device according to claim 1, wherein the first inorganic layer has a disconnected structure by the separation element.

17. The display device according to claim 1, wherein the separation element is formed of an organic material.

18. The display device according to claim 1, wherein the separation element includes:
a first part disposed over the first inorganic layer; and
a plurality of second parts which is disposed in a part in which the first inorganic layer is at least partially open.

19. The display device according to claim 18, wherein the first inorganic layer is disconnected multiple times by the plurality of second parts.

20. The display device according to claim 1, wherein the hole is disposed so as to correspond to at least one of a camera, a light sensor, a distance sensing sensor, and a face recognition sensor.

21. The display device according to claim 1, further comprising:
a plurality of second patterns disposed between the hole and the separation element and/or between the separation element and the active area.

22. The display device according to claim 21, wherein each of the plurality of second patterns includes a first sub pattern and a second sub pattern, the first sub pattern is formed of an inorganic layer, and the second sub pattern is formed of an organic layer.

23. The display device according to claim 22, wherein each of the cross-sectional shape of the first sub pattern and second sub pattern has a tapered trapezoidal shape or inversely tapered trapezoidal shape.

24. A display device, comprising:
a substrate including a first non-active area in which a hole is disposed, and an active area adjacent to the first non-active area;
a first inorganic layer disposed on the substrate;
a transistor disposed on the first inorganic layer in the active area;
a second inorganic layer and a first organic layer disposed on the transistor;
a dam which is disposed adjacent to the hole on the first inorganic layer in the first non-active area and formed by sequentially laminating the same material as the second inorganic layer and the first organic layer; and
a separation element which is disposed in the dam and is formed of the same material as the first organic layer,
wherein the separation element is disposed in an open area of the first inorganic layer which is partially open.

25. The display device according to claim 24, wherein the dam includes:
a first sub dam formed of the same material as the second inorganic layer;
a second sub dam formed of the same material as the first organic layer; and
a third sub dam disposed on the second sub dam, and
the separation element is the second sub dam.

26. The display device according to claim 24, wherein the separation element includes:
a first part disposed on the first sub dam; and
a second part which is disposed in a part in which the first inorganic layer and the first sub dam are at least partially open.

27. The display device according to claim 26, wherein the separation element includes a plurality of second parts.

28. The display device according to claim 24, further comprising:
a pattern disposed between the first inorganic layer and the second inorganic layer and the separation element.

29. The display device according to claim 24, wherein the active area is disposed to enclose the first non-active area, the dam is disposed to enclose the hole, and the separation element is disposed on the substrate exposed from the first inorganic layer.
